(19) United States
(12) Patent Application Publication
(10) Pub. No.: US 2013/0189844 A1
(43) Pub. Date: Jul. 25, 2013

(54) Method to increase the pattern density of integrated circuits using near-field EUV patterning technique

(71) Applicant: Yijian Chen, Hercules, CA (US)

(72) Inventor: Yijian Chen, Hercules, CA (US)

(73) Assignee: Vigma Nanoelectronics, Hercules, CA (US)

(21) Appl. No.: 13/374,891

(22) Filed: Jan. 23, 2012

(51) Int. Cl. H01L 21/311

(52) U.S. Cl. 438/694; 257/E21.249

(57) ABSTRACT

A novel near-field EUV patterning technique and the corresponding imaging film stacks are invented for integrated-circuit manufacturing. This invention pertains to methods of forming one and/or two dimensional features on an EUV near-field imaging material with patterned light absorbers sitting on its top. These methods can be used to produce integrated circuits with a feature density higher than what is possible using conventional EUV or optical DUV lithography.

### BACKGROUND OF THE INVENTION

As integrated-circuit technology is scaled into deep nano-scale, conventional lithography has faced increasingly difficult challenges to continuously drive down devices' feature size. A potential solution to break the diffraction limit of conventional lithography systems, near-field imaging technique, has gained extensive research interest recently. However, applying this novel technique for current leading-edge DUV (deep ultraviolet, wavelength: 193 nm) lithographic process is not possible due to its long wavelength. For example, the 193-nm exposure wavelength with a manageable propagation depth Z (e.g., about 10 nm or larger) will result in a Fresnel number w²/λZ (W: half width of an aperture, λ: wavelength [1]) small than one. This corresponds to a far-field diffraction mode that does not provide any resolution benefit to break the diffraction limit. As EUV (extreme ultraviolet, wavelength: 5-20 nm) lithography starts to mature for high-volume application, the possibility of near-field EUV imaging also emerges due to its much shorter wavelength which can bring Fresnel number into the near-field range (larger than one). Once the imaging system operates in the near field, there exist several wave peaks and valleys in the near-field region immediately underneath the opening aperture where the light propagates through. This will enable spatial frequency multiplication by a simple open-field exposure of an imaging material with patterned absorbers sitting on its top (to absorb EUV light), as shown in FIG. 1A. Moreover, recent research progress made in CVD and inorganic EUV resist [2, 3] brings this near-field patterning technique close to production worthy as the proposed near-field imaging film stack can become a routine practice in a future fab environment.

### BRIEF SUMMARY OF THE INVENTION

The EUV near-field imaging film stack is composed of a patterned absorber layer, photosensitive imaging layer, and a substrate layer. The simulated TE/TM light intensity profiles (at the observation plane in the near-field imaging layer illuminated in FIG. 1A) are shown in FIG. 1B. For this simulation, we chose hafnium-oxide's (HfO₂) n and k parameters to approximate the complex refractive index of a polymer based on a HfO₂ core. HfO₂ based polymer resist has been used for negative direct writing in e-beam lithography [2] and its core particles are used to build stable metal inorganic resists for EUV and DUV lithography [3]. As an example to demonstrate the idea, the materials of absorber/imaging/substrate used in above simulation are TaN/HfO₂/amorphous carbon (a typical hard mask material for further pattern transfer). Nevertheless, any relevant absorber/imaging/substrate materials can be adopted to construct the imaging film stack, and this patent does not limit itself to certain material choices of any layer mentioned above. Actually, HfO₂ based EUV resist has been widely reported in the lithography literature and we do not claim it as our invention.

In FIG. 1A, we show an imaging film stack on top of wafer that already has a coarse 1^{st} layer patterned by standard EUV lithography (or DUV lithography) and a following etching step (in this case TaN, pitch 60 nm, overexposed/trimmed line CD of 10 nm). After this, the wafer is exposed with open-field EUV light. According to the near-field optics, a series of patterns (with a density higher than that of patterned absorber) can be generated (and captured) in the underlying photosensitive imaging layer. It is also possible to pattern 2D contacts/pillars or random structures through this near-field imaging process. The critical issue of the film process development is to choose thin enough and robust absorber and imaging layers such that the near-field imaging process occurs while no structures will collapse due to their high aspect ratio.

### BRIEF DESCRIPTION OF THE SEVERAL VIEWS OF THE DRAWING(S)

A further understanding of the nature and advantages of the invention may be realized by reference to the specification and the drawings presented below. The figures are incorporated into the detailed description portion of the invention.

FIG. 1 shows an example of patterned film stack to achieve near-field EUV imaging (see FIG. 1A), and TE/TM image profiles in the HfO₂ layer (near field, see FIG. 1B) right underneath the opening aperture (50 nm wide). Multiple image peaks and valleys will make pitch division possible. The curve with lower peak value (or lower contrast) in FIG. 1B corresponds to the image profile formed with TM illuminatin mode, while the other curve (with higher contrast) corresponds to the image profile formed with TE illumination mode. The unit of X coordinate is μm.

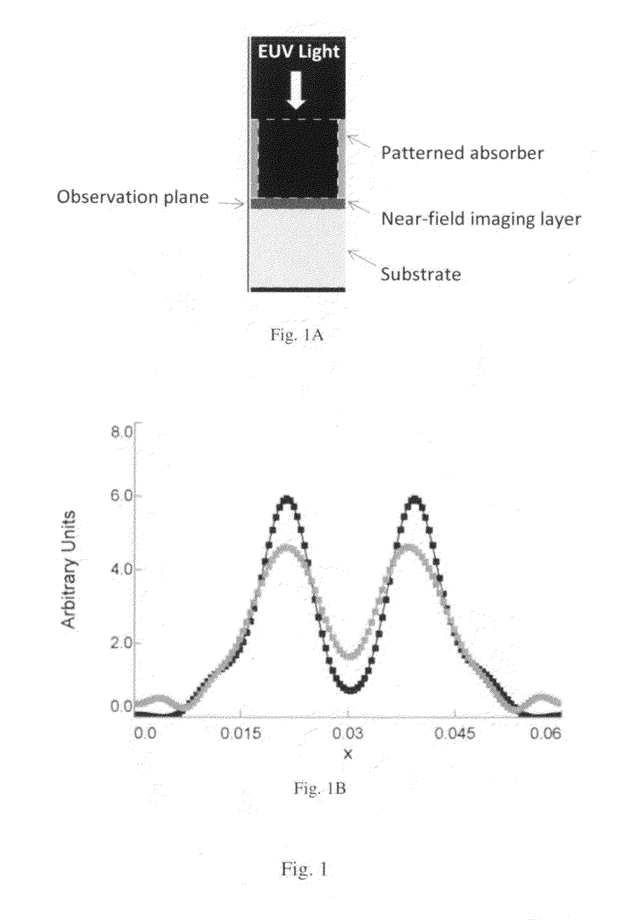

FIG. 2 illustrates the cross-sectional views representing a near-field EUV patterning process according to one embodiment of the invention.

FIG. 3 illustrates the cross-sectional views representing another near-field EUV patterning process according to the other embodiment of the invention.

FIG. 4 is a flowchart depicting steps associated with the near-field EUV patterning process described by FIG. 2.

FIG. 5 is a flowchart depicting steps associated with the near-field EUV patterning process described by FIG. 3.

### DETAILED DESCRIPTION OF THE INVENTION

Embodiments of the present invention pertain to methods of forming patterned EUV absorber features on an EUV imaging layer to produce integrated-circuit patterns with a pitch smaller than what is achievable using conventional diffraction-limited lithographic techniques.

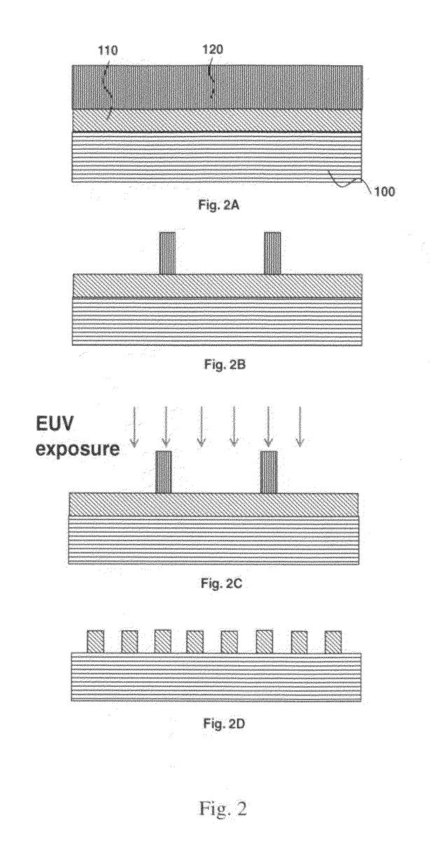

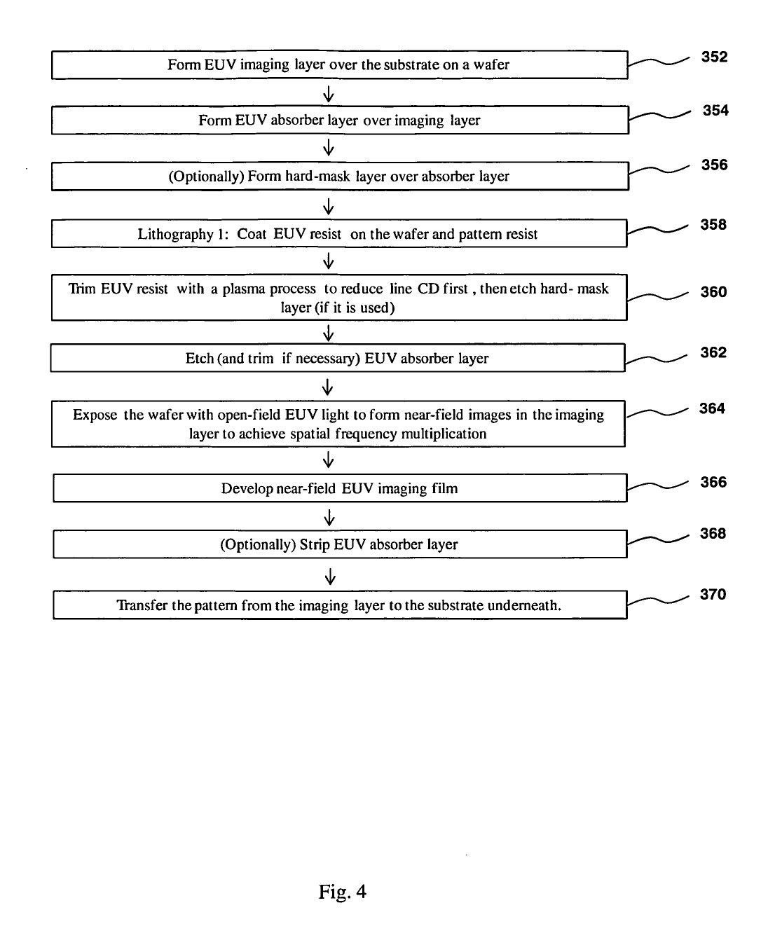

To better understand and appreciate the invention, a flowchart is shown in FIG. 4 to depict the steps associated with the patterning process according to one embodiment of the invention. The correspondingly cross-sectional views cutting through the array structure are shown in FIGS. 2A-D to illustrate the process details in above flowchart. The method starts by forming a stack of layers on a substrate 100 as shown in FIG. 2A. It is also described by operations 352-356 in the flow chart (see FIG. 4). This film stack includes a near-field EUV imaging layer 110 (which can be HfO₂ based EUV resist, CVD EUV resist, or any other relevant EUV photosensitive material that can survive the following absorber film process), and an absorber layer 120 (which can be TaN, Tin, Cr, or any other relevant absorber material). An optional hard-mask layer can be formed on top of the absorber layer, but is not shown in the figure. The absorber layer is patterned by a standard EUV lithography (operation 358) and the half pitch of patterned features is defined by the minimum resolution of an EUV tool. Once the lithographic process is completed, a plasma etching process to trim the resist CD will be performed first; and the shrunk pattern on resist will be transferred to the hard-mask layer (operation 360) and then to the absorber layer (operation 362, also shown in FIG. 2B). After the EUV absorber layer is patterned, the wafer is exposed with open-field EUV light (operation 364), as shown in FIG. 2C. According to the near-field optics, a series of patterns (with a density higher than that of patterned absorber) can be generated (and captured) in the underlying photosensitive imaging layer. The exposed wafer with near-field patterns is then developed (operation 366) and etched into the substrate layer (operation 370), as shown in FIG. 2D. It is also possible to pattern 2D contacts/pillars or random structures through this near-field imaging process.

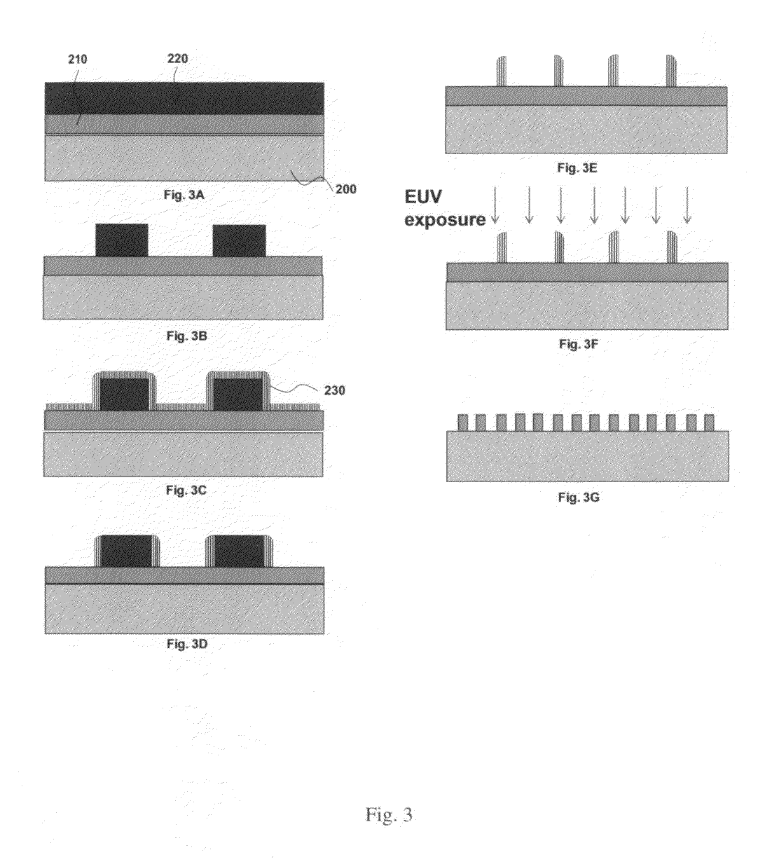

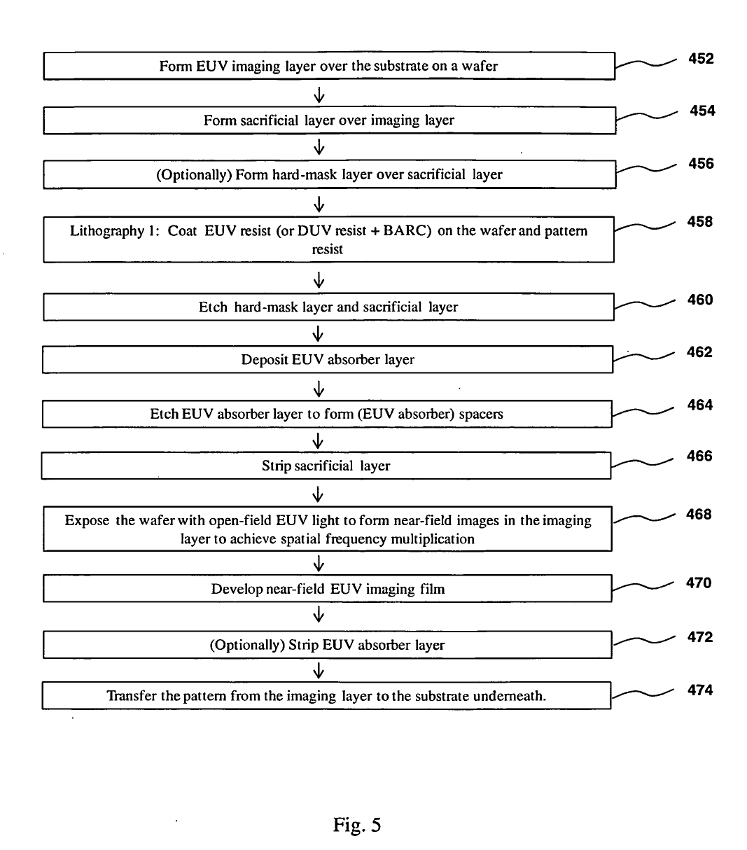

In the other process shown in FIG. 3, minor modification is made to form the absorber structures by a spacer process rather than using a lithography process. The benefit of this modified process is that optical DUV lithography can be extended to pattern the sacrificial features, thus reducing the related process costs. The corresponding process flow chart is shown in FIG. 5 to illustrate the process details. This method starts by forming a stack of layers on a substrate 200 as shown in FIG. 3A. It is also described by operations 452-456 in the flow chart (see FIG. 5). This film stack includes a near-field EUV imaging layer 210 (which can be HfO₂ based EUV resist, CVD EUV resist, or any other relevant EUV photosensitive material that can survive the following sacrificial and absorber film processes), and a sacrificial layer 220. An optional hard- mask layer can also be formed on top of the sacrificial layer, but is not shown in the figure. The sacrificial layer is patterned by a standard EUV or optical DUV lithography (operation 458, also shown in FIG. 3B) and the half pitch of patterned features is defined by the minimum resolution of the lithographic tool. Once the lithographic process is completed, a plasma etching process is used to transfer the pattern on resist to the hard-mask layer and then the sacrificial layer underneath (operation 460). After that, an EUV absorber layer is deposited (operation 462, also shown in FIG. 3C) and then etched back to form absorber spacers (operation 464, also shown in FIG. 3D), followed by a selective stripping process to remove the sacrificial structures (operation 466, also shown in FIG. 3E, stripping process does not attack the absorber spacers). The wafer is then exposed with open-field EUV light (operation 468), as shown in FIG. 3F. According to the near-field optics, a series of patterns (with a density higher than that of patterned absorber) can be generated (and captured) in the underlying photosensitive imaging layer. The exposed wafer with near-field patterns is then developed (operation 470) and etched into the substrate layer (operation 472, also shown in FIG. 3G). It is also possible to pattern 2D contacts/pillars or random structures through this near-field imaging process.

### REFERENCES

1. J. Goodman, Introduction to Fourier Optics, McGraw-Hill, 1996.

2. M. S. M. Saifullah, M. Z. R. Khan, David G. Hasko, et. al., “Spin-coatable HfO2 resist for optical and electron beam lithographies”, JVST-B, vol. 28, no. 1, pp 90, 2010.

3. Markos Trikeriotis, Woo Jin Bae, Evan Schwartz, et. al., “Development of an inorganic photoresist for DUV, EUV, and electron beam imaging”, Advances in Resist Materials and Processing Technology XXVII. Proceedings of the SPIE, Vol. 7639, 2010.

1. A novel EUV near-field patterning process comprising:
a layer of near-field EUV imaging material formed over the substrate;
an EUV absorber layer formed over the imaging layer;
a hard-mask layer formed over the absorber layer;
a lithographic step (Lithography 1) to pattern resist coated on wafer;
trimming resist CD and etching the hard-mask layer;
etching the absorber layer;
open-field EUV light exposure;
development of the exposed EUV imaging film;
(optionally) stripping the absorber layer;
pattern transfer from the imaging layer to substrate by a dry etch process;

2. The method of claim 1 wherein the absorber structures are formed by a spacer process and a following sacrificial stripping process.

3. The method of claim 1 wherein the absorber material is TaN.

4. The method of claim 1 wherein the absorber material is TiN.

5. The method of claim 1 wherein the absorber material is Cr.

6. The method of claim 1 wherein the imaging material is HfO₂ based EUV resist.

7. The method of claim 1 wherein the imaging material is CVD EUV resist.

8. The method of claim 1 wherein the imaging material is inorganic EUV resist.
